(19) United States
(12) Patent Application Publication
(10) Pub. No.: US 2023/0042063 A1
(43) Pub. Date: Feb. 9, 2023

(54) SEMICONDUCTOR PACKAGE

(71) Applicant: SAMSUNG ELECTRONICS CO., LTD., SUWON-SI (KR)

(72) Inventors: SEONGHOON BAE, CHEONAN-SI (KR); JUIL CHOI, SEONGNAM-SI (KR); GYUHO KANG, CHEONAN-SI (KR); JONGHO PARK, CHEONAN-SI (KR); ATSUSHI FUJISAKI, SEONGNAM-SI (KR)

(21) Appl. No.: 17/852,054

(22) Filed: Jun. 28, 2022

(30) Foreign Application Priority Data
Aug. 9, 2021 (KR) 10-2021-0104812

(51) Int. Cl. H01L 25/065; H01L 23/538; H01L 23/367; H01L 23/31; H01L 23/00

(52) U.S. Cl. CPC H01L 25/0655; H01L 23/5383; H01L 23/367; H01L 23/3128; H01L 24/32; H01L 2224/32137; H01L 2224/2919; H01L 24/29

(57) ABSTRACT

A semiconductor package includes; laterally stacked semiconductor blocks disposed side by side in a first horizontal direction on a redistribution structure, wherein each semiconductor block among the laterally stacked semiconductor blocks includes laterally stacked semiconductor chips, a heat dissipation plate, and a first molding member on the laterally stacked semiconductor chips.

### CROSS-REFERENCE TO RELATED APPLICATION

This application claims priority under 35 U.S.C. §119 to Korean Patent Application No. 10-2021-0104812 filed on Aug. 9, 2021 in the Korean Intellectual Property Office, the subject matter of which is hereby incorporated by reference in its entirety.

### BACKGROUND

The inventive concept relates to semiconductor packages. More particularly, the inventive concept relates to semiconductor packages that efficiently mount semiconductor chip(s) in a limited structure thereof.

Recently, in the electronics market, demands for portable devices are rapidly increasing. Therefore, electronic parts mounted in electronic products are continuously required to become smaller and lighter. In order to make the electronic parts smaller and lighter, semiconductor package technology of integrating a plurality of individual elements into one package as well as technology of reducing sizes of the mounted electronic parts is required. In particular, as a high-capacity semiconductor is required, the number of semiconductor chips mounted in the semiconductor package increases. Due to a space constraint of the semiconductor package, technology of reducing the space constraint by changing a method of arranging the semiconductor chips is required.

### SUMMARY

The inventive concept relates to a semiconductor package capable of reducing a space constraint by changing a method of arranging semiconductor chips in order to increase the number of semiconductor chips mounted in the semiconductor package.

According to an aspect of the inventive concept, there is provided a semiconductor package including; laterally stacked semiconductor blocks disposed side by side in a first horizontal direction on a redistribution structure, wherein each semiconductor block among the laterally stacked semiconductor blocks includes laterally stacked semiconductor chips, a heat dissipation plate, and a first molding member on the laterally stacked semiconductor chips.

According to another aspect of the inventive concept, there is provided a semiconductor package including; a redistribution structure extending in a first horizontal direction, solder bumps arranged on a bottom surface of the redistribution structure, laterally stacked semiconductor blocks arranged side by side on a top surface of the redistribution structure, wherein adjacent semiconductor blocks among the laterally stacked semiconductor blocks are separated by a heat dissipation plate, each of the laterally stacked semiconductor blocks includes laterally stacked semiconductor chips and a first molding layer on the laterally stacked semiconductor chips, and each semiconductor chip among the laterally stacked semiconductor chips includes a semiconductor substrate and a redistribution layer on the semiconductor substrate.

According to another aspect of the inventive concept, there is provided a semiconductor package including; a laterally stacked plurality of semiconductor chips, wherein each semiconductor chip among the laterally stacked plurality of semiconductor chips includes; a semiconductor substrate having an active surface and an opposing inactive surface facing, a first side and an opposing second side respectively connecting the active surface and the inactive surface, and a redistribution layer on the active surface, adhesive layers respectively disposed between adjacent ones of the laterally stacked plurality of semiconductor chips, a redistribution structure extending in a first horizontal direction, wherein the laterally stacked plurality of semiconductor chips is disposed on a top surface of the redistribution structure, such each first side of the laterally stacked plurality of semiconductor chips contacts the top surface of the redistribution structure, a plurality of heat dissipation plates, wherein each heat dissipation plate among the plurality of heat dissipation plates is respectively disposed at a regular interval among the laterally stacked plurality of semiconductor chips, and a first molding member covering at least two second sides of the laterally stacked plurality of semiconductor chips and exposing an end portion of each one of the plurality of heat dissipation plates.

### BRIEF DESCRIPTION OF THE DRAWINGS

Embodiments of the inventive concept will be more clearly understood from the following detailed description taken in conjunction with the accompanying drawings in which:

FIG. 1A is a plan view illustrating a semiconductor package 10 according to embodiments of the inventive concept, FIG. 1B is another cross-sectional view taken along line X-X′ in the semiconductor package 10 of FIG. 1A, and FIG. 1C is a perspective view further illustrating an enlarged portion of the semiconductor block of FIG. 1B;

FIGS. 2, 3, 4 and 5 are respective cross-sectional views illustrating semiconductor packages according to embodiments of the inventive concept;

FIG. 6 is a flowchart summarizing in one example a method of manufacturing a semiconductor package according to embodiments of the inventive concept;

FIGS. 7A, 7B, 7C, 7D, 7E, 7F and 7G (hereafter collectively, “FIGS. 7A to 7G”) are related cross-sectional views illustrating in one example a method of manufacturing a semiconductor package according to embodiments of the inventive concept; and

FIG. 8 is a block diagram illustrating one possible configuration of a semiconductor package according to embodiments of the inventive concept.

### DETAILED DESCRIPTION

Throughout the written description and drawings, like reference numbers and labels are used to denote like or similar elements, components, method steps and/or features. Throughout the written description certain geometric terms may be used to highlight relative relationships between elements, components and/or features with respect to certain embodiments of the inventive concept. Those skilled in the art will recognize that such geometric terms are relative in nature, arbitrary in descriptive relationship(s) and/or directed to aspect(s) of the illustrated embodiments. Geometric terms may include, for example: height/width; vertical/horizontal; top/bottom; higher/lower; closer/farther; thicker/thinner; proximate/distant; above/below; under/over; upper/lower; center/side; surrounding; overlay/underlay; etc.

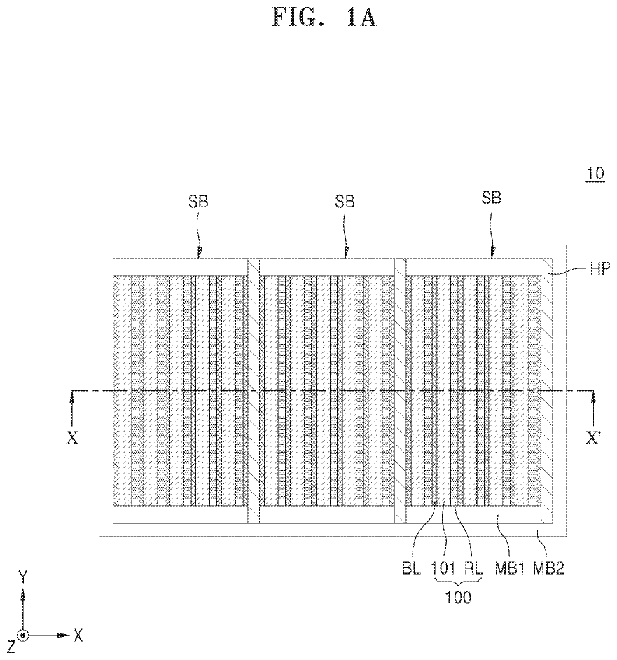

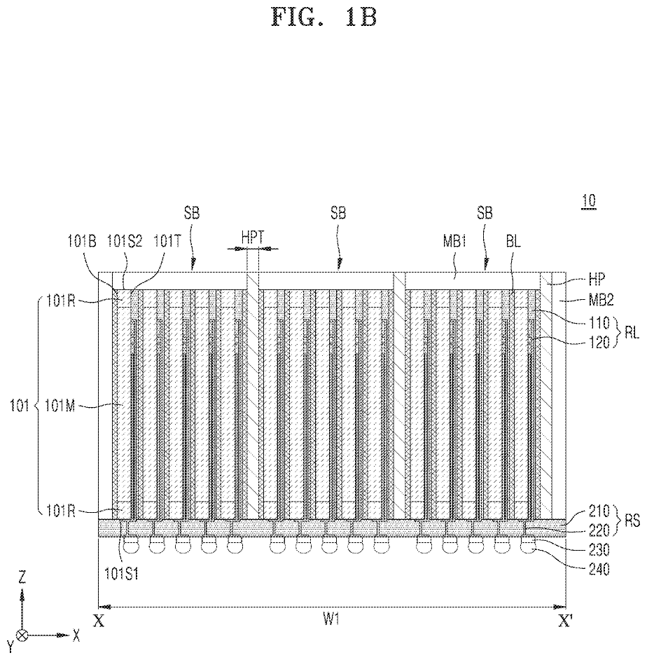

FIG. 1A is a plan view illustrating a semiconductor package 10 according to embodiments of the inventive concept, FIG. 1B is a cross-sectional view taken along line X-X′ in the semiconductor package 10 of FIG. 1A, and FIG. 1C is a perspective view further illustrating an enlarged version of a semiconductor block in FIGS. 1A and 1B.

Referring to FIGS. 1A, 1B and 1C, the semiconductor package 10 includes multiple semiconductor blocks SB on a redistribution structure RS.

Each of the semiconductor blocks SB included in the semiconductor package 10 may include multiple semiconductor chips 100, multiple adhesive layers BL respectively attaching the semiconductor chips 100, a heat dissipation plate HP arranged external to (or on the periphery of) the semiconductor chips 100, and a first molding member MB1 substantially surrounding the semiconductor chips 100.

In some embodiments, the semiconductor package 10 may include a lateral stack of semiconductor blocks SB, wherein each semiconductor block SB includes a lateral stack of semiconductor chips 100. In this context, the term “lateral stack” refers to an arrangement of semiconductor chips 100, wherein each semiconductor chip 100 in the arrangement is stood on edge, such that opposing upper and lower surfaces (e.g., active and inactive surfaces) of the semiconductor chip 100 extend upward in a second horizontal (or Y) direction and a vertical (or Z) direction. With this orientation, respective semiconductor chips 100 may be laterally stacked, one on top of the other, in a first horizontal (or X) direction within each semiconductor block SB.

Thereafter, given two or more semiconductor blocks SB having the foregoing configuration, the respective semiconductor blocks SB may be laterally stacked in the first horizontal direction to form the semiconductor package 10.

In some embodiments consistent with the foregoing, each of the semiconductor blocks SB may have the shape of a regularly-sided, rectangular cube including an alternating and laterally stacked arrangement of semiconductor substrates 101 and corresponding redistribution layers RL. Each of the semiconductor blocks SB may further include a heat dissipation plate HP laterally stacked on one end.

As illustrated in FIG. 1B, the laterally stacked semiconductor blocks SB may be collectively disposed on a top surface of the redistribution structure RS, described in some additional detail hereafter. With this configuration, a bottom (or lower) edge of each semiconductor block SB may directly contact the top surface of the redistribution structure RS.

Each of the semiconductor chips 100 may include one or more volatile memory chip(s) (e.g., a dynamic random access memory (RAM) (DRAM), a static RAM (SRAM), a thyristor RAM (TRAM), a zero capacitor RAM (ZRAM), a twin transistor RAM (TTRAM), etc.) and/or one or more non-volatile memory chip(s) (e.g., a flash memory, a magnetic RAM (MRAM), a spin-transfer torque MRAM (STT-MRAM), a ferroelectric RAM (FRAM), a phase change RAM (PRAM), a resistive RAM (RRAM), a nanotube RRAM, polymer RAM, an insulator resistance change memory, etc.).

In some embodiments, a semiconductor chip 100 may include a memory chip set including multiple memory chips (e.g., high bandwidth (HBW) memory chips).

Each of the semiconductor chips 100 may include a semiconductor substrate 101 having an active surface and an opposing inactive surface, and the redistribution layer RL disposed on the active surface of the semiconductor substrate 101.

The semiconductor substrate 101 may include a top surface 101T and an opposing bottom surface 101B, as well as a first side (or downward extending edge) 101S1 and an opposing second side (or upward extending edge) 101S2. Here, the top surface 101T may be referred to as the active surface and the bottom surface 101B may be referred to as the inactive surface. The semiconductor substrate 101 may include the redistribution layer RL formed on the top surface 101T thereof and the adhesive layer BL arranged on the bottom surface 101B thereof. In addition, the first side 101S1 of the semiconductor substrate 101 may contact the redistribution structure RS and the second side 101S2 of the semiconductor substrate 101 may contact the first molding member MB1.

The semiconductor substrate 101 may include, for example, a silicon (Si) (e.g., crystalline silicon, polycrystalline silicon, amorphous silicon, etc.). Alternately, the semiconductor substrate 101 may include a semiconductor element such as germanium (Ge) or a compound semiconductor such as silicon carbide (SiC), gallium arsenide (GaAs), indium arsenide (InAs), indium phosphide (InP), etc.

In some embodiments, the semiconductor substrate 101 may have a silicon-on-insulator (SOI) structure. For example, the semiconductor substrate 101 may include a buried oxide (BOX) layer. In some embodiments, the semiconductor substrate 101 may include one or more conductive area(s) (e.g., a well, a region or a structure variously doped with one or more impurities). In addition, the semiconductor substrate 101 may include one or more isolation structures, such as a shallow trench isolation (STI) structure.

In some embodiments, each semiconductor substrate 101 may include a main area 101M in which one or more semiconductor devices may be arranged, and one or more scribe lane area(s) 101R arranged on an edge of the main area 101M.

The redistribution layer RL may be formed on the top surface 101T of the semiconductor substrate 101. The redistribution layer RL may include a first wiring layer 120 configured to variously connect semiconductor device(s) on the active surface of the semiconductor substrate 101 to the redistribution structure RS, and a first insulating layer 110 surrounding the first wiring layer 120. The first wiring layer 120 may include various combinations of metal wiring layers and via plugs. For example, the first wiring layer 120 may have a multilayer structure in which two or more metal wiring layers and/or two or more via plugs are alternately stacked. Here, the redistribution layer RL may be disposed in both the main area 101M and the scribe lane area 101R of the semiconductor substrate 101.

The adhesive layer BL may be arranged on the bottom surface 101B of the semiconductor substrate 101. In this manner, adhesive layers BL may be used to attach the laterally stacked semiconductor chips 100 one to another. In some embodiments, the adhesive layer BL may include a die attach film. The die attach film may be divided into an inorganic adhesive and a polymer adhesive. Polymer may be divided into thermosetting resin and thermoplastic resin. Here, thermosetting resin may have a three-dimensional cross-link structure after monomer(s) are heat molded that will not again soften even when reheated. Alternately, thermoplastic resin may exhibit a plasticity caused by heating a linear polymer structure. In addition, hybrid polymer generated by mixing thermosetting resin with thermoplastic resin may be used.

The heat dissipation plate HP may be disposed on one end of each semiconductor block SB. For example, the heat dissipation plate HP may be attached to the laterally stacked arrangement of semiconductor chips 100 using the adhesive layer BL. The heat dissipation plate HP may include at least one thermally conductive material(s), such as copper (Cu), aluminum (Al), titanium (Ti), tantalum (Ta), tungsten (W) and nickel (Ni). Here, a metal paste or a metal tape maybe used.

Thermal energy (or heat) generated by the semiconductor chips 100 may be exhausted (e.g., dissipated or conducted away from) the semiconductor package 10 by the various heat dissipation plate(s) HP. In this regard, at least part (e.g., an outer edge) of each heat dissipation plate HP may extend outward beyond an outer edge of the first molding member MB1 to better exhaust heat. That is, at least part of each heat dissipation plate HP may not be covered by the first molding member MB1. Alternately or additionally, each heat dissipation plate HP may be configured to impede transfer of heat from one semiconductor block SB to a neighboring semiconductor block SB.

In this regard, each of the heat dissipation plates HP may have thickness HPT that ranges from between about 10 μm to about 30 μm. In addition, a first planar area 101A of the semiconductor substrate 101 may be less than a second planar area HPA of the heat dissipation plate HP. That is, in some embodiments, the semiconductor substrate 101 may have a first length 101L that is less than a second length HPL of the heat dissipation plate HP. Here, the term “length” denotes a distance measured in the vertical direction from an arbitrarily selected horizontal plane (e.g., the top surface of the redistribution structure RS).

In some embodiments, an equal number (e.g., a natural number, ‘N’) of semiconductor chips 100 may be laterally stacked between adjacent heat dissipation plates HP. In some embodiments, N may range from 2 to 5.

The first molding member MB1 may substantially surround the laterally stacked semiconductor chips 100 in each semiconductor block SB to protect the semiconductor chips 100 from external shock and/or contamination. The first molding member MB1 may include an epoxy mold compound or resin. In addition, the first molding member MB1 may be formed by a process such as compression molding, lamination, or screen printing. In some embodiments, at least part of the heat dissipation plate HP may not be covered by the first molding member MB1.

As noted above, laterally stacked semiconductor blocks SB may be collectively disposed on the redistribution structure RS within the semiconductor package 10. For example, the laterally stacked semiconductor blocks SB may be disposed on a substantially flat, top surface of the redistribution structure RS.

Here, the redistribution structure RS may include second wiring layers 220 configured to variously connect the first wiring layers 120 associated with the redistribution layers RL of the semiconductor chips 100, and a second insulating layer 210 substantially surrounding the second wiring layers 220. Analogous to the first wiring layer 120, the second wiring layer 220 may include one or more metal wiring layer(s) and a via plug(s). For example, the second wiring layer 220 may have a multilayer structure in which two or more metal wiring layers and/or two or more via plugs are alternately stacked.

In some embodiments, the redistribution structure RS may have a first width W1. Here, the term “width” denotes a distance measured in the first horizontal direction. The first width W1 may vary in accordance with the number of semiconductor blocks SB included in the semiconductor package 10.

The second insulating layer 210 may include, for example, silicon oxide, silicon nitride, silicon oxynitride, one or more polymer(s), a benzocyclobutene, one or more resin(s), one or more photosensitive polyimide(s), etc.

The second wiring layer 220 may include at least one of, for example, Cu, Ni, gold (Au), chrome (Cr), Ti, and palladium (Pd). In some embodiments, the second wiring layer 220 may be formed using an electroplating process.

In the semiconductor package 10 of FIGS. 1A, 1B and 1C, the top surface of the redistribution structure RS may be substantially perpendicular to top surfaces 101T of the respective semiconductor substrates 101, such that the top surface of the redistribution structure RS may respectively contact the first sides 101S1 of the semiconductor substrates 101. Thus, in some embodiments, at least a portion of the top surface of the redistribution structure RS may effectively contact a first side (101S1) of each redistribution layer RL and a first side (101S1) of each heat dissipation plate HP.

With this configuration, the respective first wiring layers 120 may be variously connected to the second wiring layers 220. In addition, the second wiring layers 220 may be variously connected to pillar layers 230 and corresponding connection terminals 240. Here, the pillar layers 230 and the connection terminals 240 may be arranged on a bottom surface of the redistribution structure RS, and variously configured to interconnected the semiconductor chips 100 and/or externally connect the semiconductor chips 100 through the first wiring layers 120 and the second wiring layers 220.

In this regard, the connection terminals 240 may include solder balls or solder bumps (e.g., a lead-free solder including tin (Sn)). Accordingly, the semiconductor package 10 may be variously connected to one or more external devices (e.g., a main board) through the connection terminals 240, the pillar layers 230, and the redistribution structure RS.

A second molding member MB2 may be arranged on the redistribution structure RS to at least partially surround the outer lateral surfaces of the laterally stacked semiconductor blocks SB. However, the second molding member MB2 may leave expose both sides of the redistribution structure RS, as well as upwardly extending end portions of the heat dissipation plates HP.

In this regard, the second molding member MB2 may be understood as an exterior portion of the semiconductor package 10. Although not shown, a marking pattern including information on the semiconductor package 10 (e.g., a barcode, a QR code, a number, a message, and/or a sign) may be presented on a side of the second molding member MB2.

The second molding member MB2 may serve to further protect the semiconductor blocks SB against external shocks and/or contamination. The second molding member MB2 may include an epoxy mold compound or resin. In addition, the second molding member MB2 may be formed by a process such as compression molding, lamination, or screen printing. In some embodiments, the second molding member MB2 may include the same material(s) as the first molding member MB1, and may be formed using the same process(es) used to form the first molding member MB1.

Against the backdrop of the foregoing technical description, it should be noted that consumer demands for more powerful portable electronic devices continues to expand. Accordingly, there are consistent demands for constituent components of such portable device (e.g., semiconductor packages) that are smaller, lighter while also exhibiting expanded functionality with reduced power consumption. In order to address these demands, among other demands, semiconductor packages consistent with embodiments of the inventive concept integrate a greater number of elements and components (e.g., semiconductor chips) into a single package. However, due to size and space constraints inherent in contemporary and emerging the semiconductor packages, different approaches (e.g., methods and architectures) have been investigated which seek to better arrange semiconductor chips within the available size and space constraints.

For example, previous approaches have vertically stacked a number of semiconductor chips using through silicon via(s) (TSV) that pass through the semiconductor chips and/or bonding wires that extend around edges of the vertically stacked semiconductor chips. However, the use of TSVs is relatively costly, the use of bonding wires requires considerable lateral space around the vertically stacked semiconductor chips. In addition, due to various limitations associated with vertical stacking technologies and related structural limitations, it is difficult to vertically stack more than twenty (20) semiconductor chips in a semiconductor package.

In contrast, embodiments of the inventive concept are not limited by such constraints since multiple semiconductor chips may be laterally stacked (e.g., in a first horizontal direction and/or a second horizontal direction) within a semiconductor package. Accordingly, as demonstrated by contemporary studies, embodiments of the inventive concept may laterally stack one hundred or more semiconductor chips using an arrangement of semiconductor blocks SB within a semiconductor package, like the semiconductor package 10 of FIGS. 1A, 1B and 1C.

In addition, by arranging the redistribution layers RL and the redistribution structure RS as described above the laterally stacked semiconductor chips may be vertically contacted without requirement of TSVs and/or bonding wires.

Further, heat dissipation issues routinely associated with stacked arrangements of semiconductor chips may be better address by the selective inclusion (e.g., the lateral stacking) of heat dissipation plate(s) HP among the semiconductor chips.

As a result of the foregoing, semiconductor packages according to embodiments of the inventive concept are able to provide higher memory capacity, improved manufacturing economy, expanded functionality, greater production efficiencies and/or reduced power consumption, as compared with conventional semiconductor packages including vertically stacked semiconductor chips connected by TSVs and/or bonding wires.

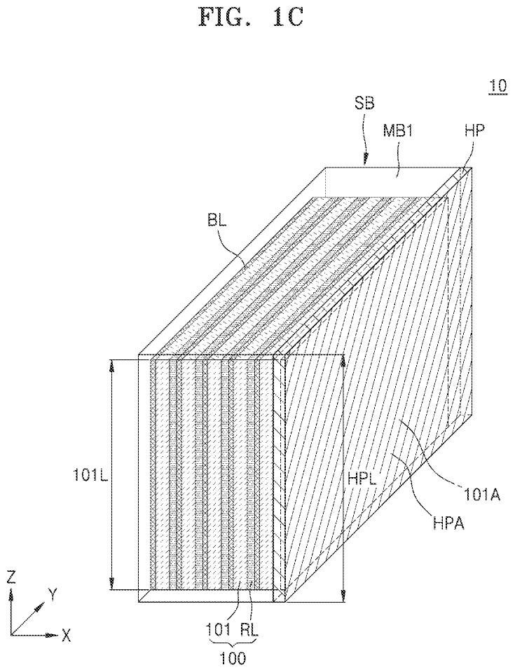

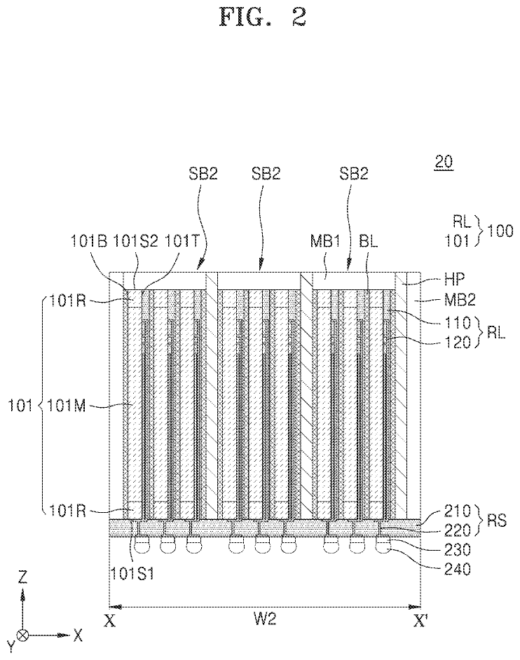

FIGS. 2, 3, 4 and 5 are respective cross-sectional views variously illustrating semiconductor packages according to embodiments of the inventive concept. The following detailed description of embodiments focuses primarily on differences between the embodiment of FIGS. 1A, 1B and 1C and other embodiments of the inventive concept.

Referring to FIG. 2, a semiconductor package 20 includes a combination of laterally stacked semiconductor blocks SB2 disposed on the redistribution structure RS.

Here, it is assumed for purposes of illustration that each semiconductor block SB2 includes three (3) semiconductor chips 100 (i.e., N=3 in the illustrated example of FIG. 2). However, those skilled in the art will appreciate that any reasonable number of semiconductor chips 100 may be included in each semiconductor block SB2.

In some embodiments, a same number of semiconductor chips 100 may be arranged in each semiconductor block SB2.

The semiconductor blocks SB2 may be arranged in relation to a number of heat dissipation plates HP. For example, each semiconductor block SB2 may be arranged a one (1) one heat dissipation plate HP. Accordingly, heat generated by the semiconductor chips 100 may be exhausted from the semiconductor package 20 through the heat dissipation plates HP. Further, the respective heat dissipation plates HP may impede or prevent heat generated by one semiconductor block SB2 from being transferred (e.g., thermally conducted) to another, neighboring semiconductor block SB2. It follows that where one or more of the semiconductor blocks SB2 is expected to produce relatively large quantities of heat requiring exhaust, the number ‘N’ of semiconductor chips 100 in such semiconductor blocks SB2 may be relatively few, or at least relatively few for a number of heat dissipation plates included in the semiconductor block SB2.

In some embodiments like the semiconductor package 20 of FIG. 2, the redistribution structure RS may have a second width W2 that is largely determined by the number of semiconductor chips 100 included in each of the semiconductor blocks SB2.

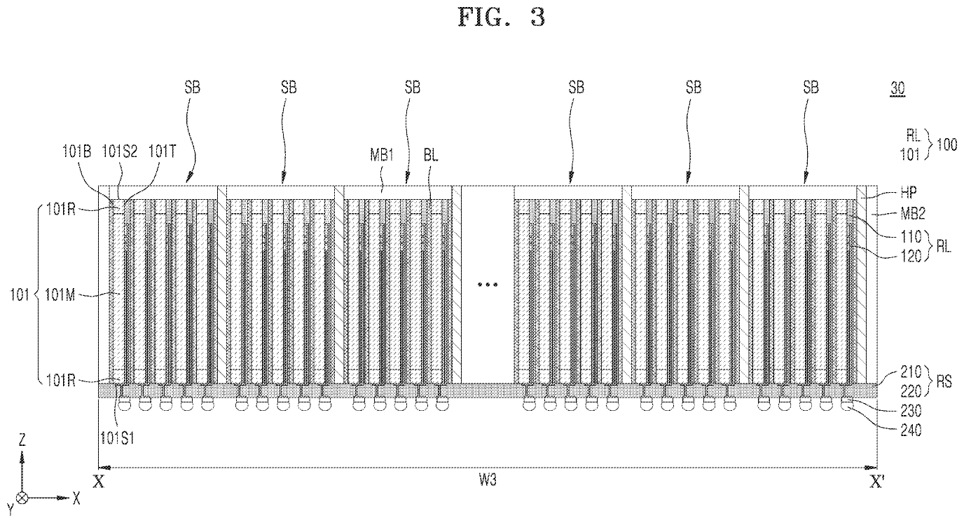

Referring to FIG. 3, a semiconductor package 30 may again generally include an arrangement of laterally semiconductor blocks SB disposed on the redistribution structure RS.

However, the semiconductor package 30 may have a third width W3 that is largely determined by the number of semiconductor blocks SB included in the semiconductor package 30. In this regard, any reasonable number of semiconductor blocks SB may be laterally stacked within the semiconductor package 30. Further, in some embodiments, each of the semiconductor blocks SB included within the semiconductor package 30 may have the same (e.g., a standard size) size and include the same number of semiconductor chips 100. Alternately, a variety of semiconductor blocks SB having different sizes (e.g., different widths) and including a different number of semiconductor chips 100 may be laterally stacked within the semiconductor package 30. In some embodiments, different semiconductor blocks SB may have different thermal exhaust requirements, depending on the nature and arrangement of semiconductor chips therein.

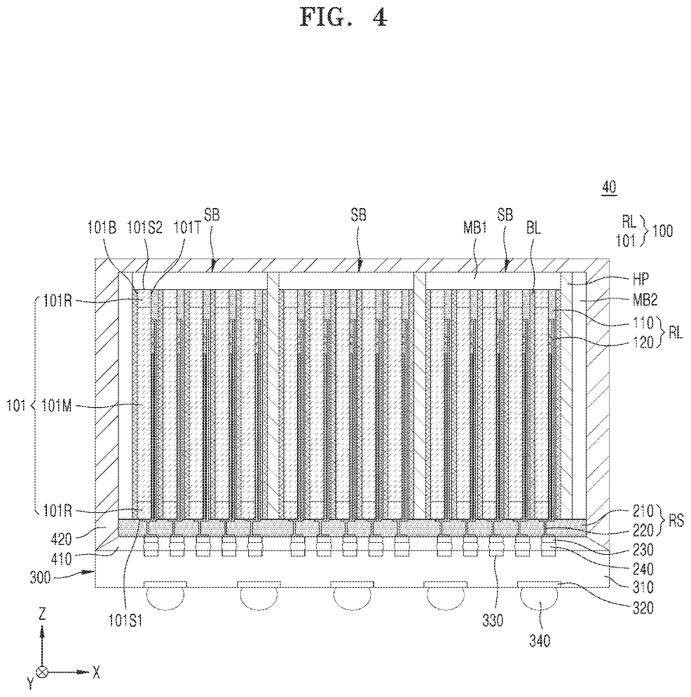

Referring to FIG. 4, a semiconductor package 40 may include a base substrate 300 and a combination of laterally stacked semiconductor blocks SB mounted on a top surface of the base substrate 300.

Here, the base substrate 300 may include at least one of a printed circuit board (PCB), a ceramic substrate, and an interposer.

In some embodiments, assuming that the base substrate 300 includes a PCB, the base substrate 300 may include a substrate body 310, lower pads 320, upper pads 330, and respective solder resist layers (not shown) formed on a bottom surface and a top surface of the substrate body 310. Internal wiring (not shown) disposed in the substrate body 310 may be used to variously connect the lower pads 320 and the upper pads 330. The lower pads 320 and the upper pads 330 may be respectively and selectively exposed through the solder resist layers on the bottom surface and the top surface of the substrate body 310. Additional circuit wiring(s) may be formed using conductive coating(s) on the bottom surface and/or the top surface of the substrate body 310. for example, copper (Cu) foil may be disposed (e.g., coated on) and patterned on the bottom surface and/or the top surface of the substrate body 310.

In other embodiments, assuming that the base substrate 300 includes an interposer, the base substrate 300 may include the substrate body 310 including a semiconductor material and the lower pads 320 and the upper pads 330 respectively formed on the bottom surface and the top surface of the substrate body 310. The substrate body 310 may include, for example, a silicon wafer. Internal wiring (not shown) may be formed on the bottom surface and/or the top surface of the substrate body 310. Internal wiring may also be formed within the substrate body 310. One or more through vias (not shown), in conjunction with the internal wiring(s), maybe used to variously connect the lower pads 320 and the upper pads 330.

External connection terminals 340 may be attached to a bottom surface of the base substrate 300. In some embodiments, the external connection terminals 340 may be attached using the lower pads 320. The external connection terminals 340 may include, for example, solder balls or solder bumps. The external connection terminals 340 may be used to connect the semiconductor package 40 with one or more external device(s).

An underfill 410 may be formed between the base substrate 300 and the redistribution structure RS, and may substantially surround connection terminals 240. The underfill 410 may include, for example, epoxy resin. In some embodiments, the underfill 410 may be part of a second molding member 420 formed by using a molded underfill (MUF) method. In other embodiments, a non-conductive film (NCF) may be used instead of the underfill 410.

The second molding member 420 substantially surrounding the laterally stacked semiconductor blocks SB may be formed on the base substrate 300. Thus, the second molding member 420 may serve as exterior side and top surfaces of the semiconductor package 40 while protecting the semiconductor blocks SB from shock and/or contamination.

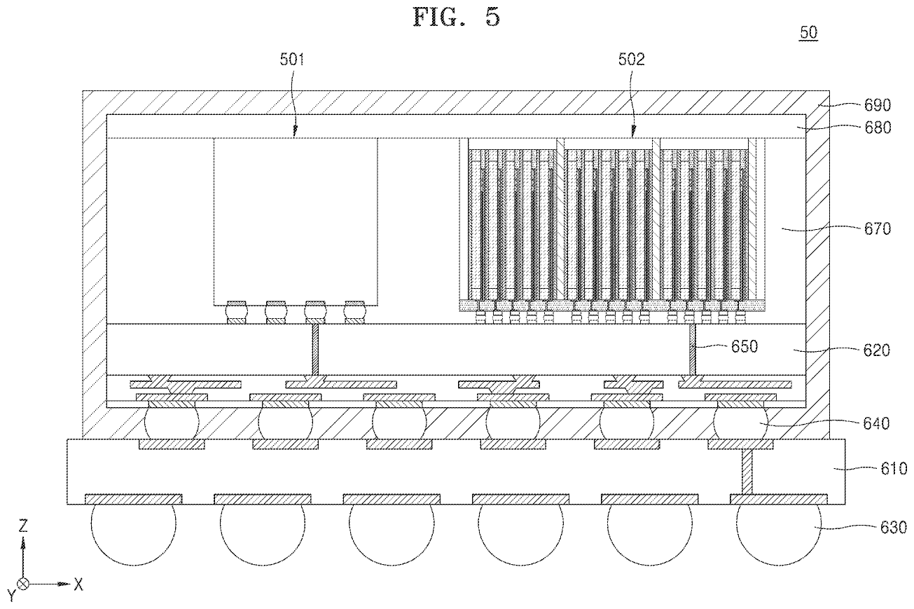

Referring to FIG. 5, a semiconductor package 50 may include a package substrate 610, an interposer 620 disposed on the package substrate 610, and first and second semiconductor devices 501 and 502 disposed on a top surface of the interposer 620 and laterally spaced apart in the first horizontal direction.

The package substrate 610 included in the semiconductor package 50 may include at least one of, for example, a PCB, a wafer substrate, a ceramic substrate, and a glass substrate.

External connection terminals 630 may be arranged on a bottom surface of the package substrate 610. Hence, the semiconductor package 50 may mounted (e.g., mechanically assembled and/or electrically connected) on a module substrate or a system board of an electronic product using the external connection terminals 630.

The interposer 620 may include internal connection terminals 640 connected to a bottom thereof. The internal connection terminals 640 may be variously connected to the first and second semiconductor devices 501 and 502 using (e.g.,) through vias 650. In addition, first bump pads 660 may be arranged on the top surface of the interposer 620.

In the semiconductor package 50, the first and second semiconductor devices 501 and 502 may be mounted on the interposer 620, and a molding member 670 may be disposed to substantially surround the first and second semiconductor devices 501 and 502, as well as a heat dissipation member 680 disposed on the molding member 670. In some embodiments, the semiconductor package 50 may include an encapsulation 690 surrounding the interposer 620, the molding member 670, and the heat dissipation member 680.

The first semiconductor device 501 may be implemented by a microprocessor, a graphics processor, a signal processor, a network processor, a chipset, an audio codec, a video codec, an application processor, or a system on chip (SoC) as a single logic chip. In contrast, the second semiconductor device 502 may include a high bandwidth memory (HBM) chip in which a plurality of slices are arranged to form a stacked structure.

In the semiconductor package 50, laterally stacked semiconductor blocks SB may be included in the second semiconductor device 502 and may be substantially similar in composition and operative nature as the semiconductor packages 10, 20, 30 and 40 previously described.

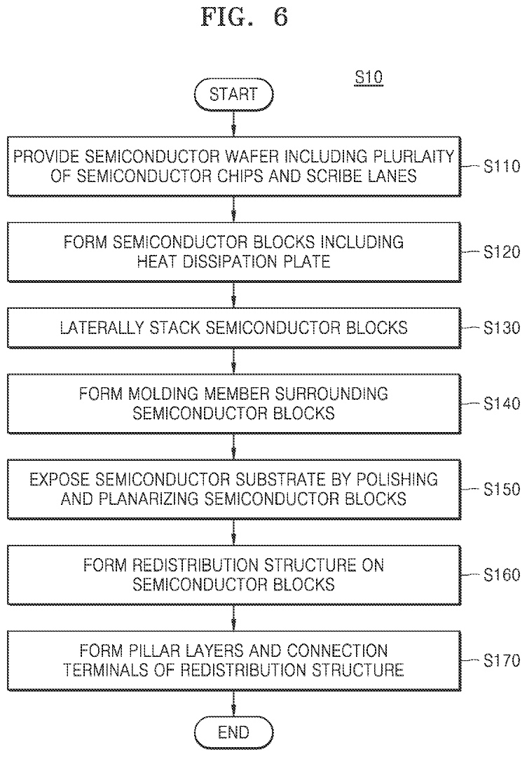

FIG. 6 is a flowchart summarizing in one example (S10) a method of manufacturing a semiconductor package according to embodiments of the inventive concept.

Referring to FIG. 6, the semiconductor package manufacturing method S10 may include providing a semiconductor wafer including a plurality of semiconductor chips 100 and appropriately marked with scribe lanes (S110). Thereafter, the plurality of semiconductor chips 100 may be separated (or singulated) from the wafer using (e.g.,) a sawing method.

Using the singulated semiconductor chips 100, respective semiconductor blocks (SB) may be formed (S120). For example, a number ‘N’ of semiconductor chips may be sequentially stacked on a first (or temporary) carrier substrate.

Thereafter, two or more of the semiconductor blocks SB may be laterally stacked (S130). For example, semiconductor blocks SB may be sequentially arranged, rotated (or stood on edge), and then disposed on a second carrier substrate. This approach, among others, may be used to laterally stack a number of semiconductor block side by side in a horizontal direction (e.g., a first horizontal direction).

A molding member may be formed that substantially surrounds the laterally stacked semiconductor blocks SB (S150). In this regard, the molding member may leave expose portions of the laterally stacked semiconductor blocks, such as an upward edge surface that will ultimately be disposed on a redistribution structure RS.

Further in this regard, upward edge portions, for example, of the constituent semiconductor substrates corresponding to the various semiconductor chips 100 arranged in the laterally stacked semiconductor blocks SB may be exposed for further processing using a polishing and/or planarizing processes (S160).

Thereafter, various pillar layer(s), connection pads, wiring layer(s), insulation layer(s) and/or connection terminals may be variously disposed to mount the redistribution structure RS on the prepared (e.g., polished and/or planarized) flat surface of the laterally stacked semiconductor blocks SB (S170). And the second carrier substrate may be removed.

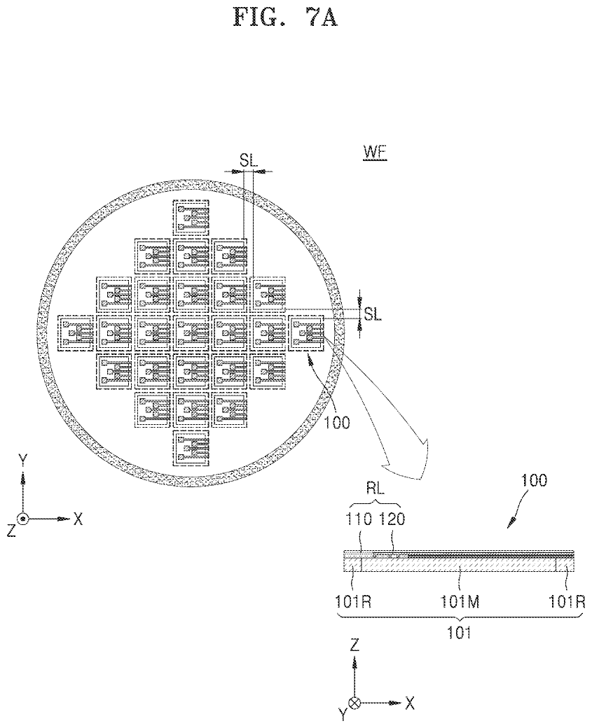

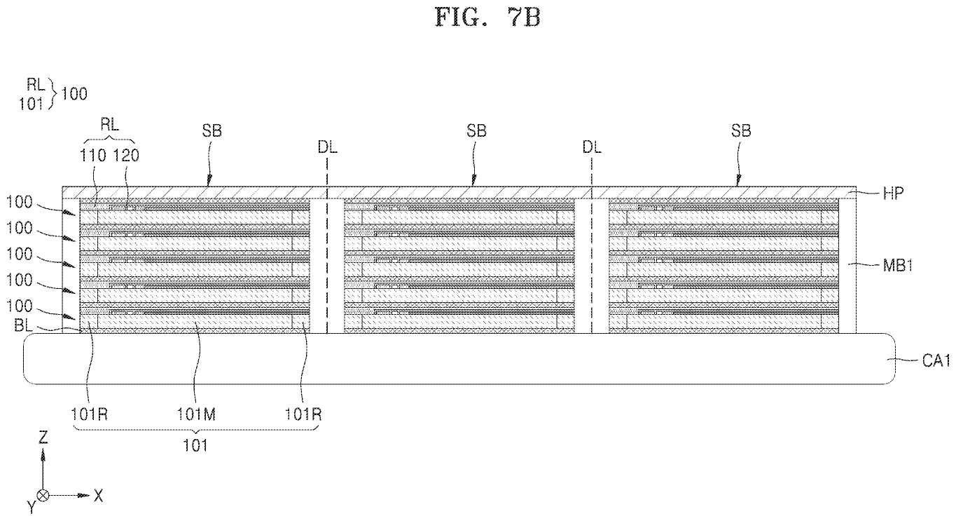

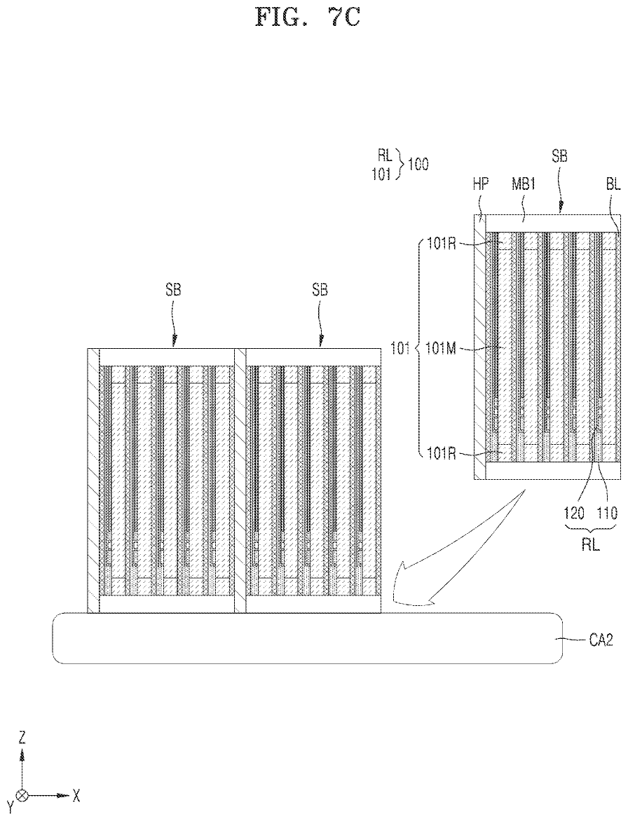

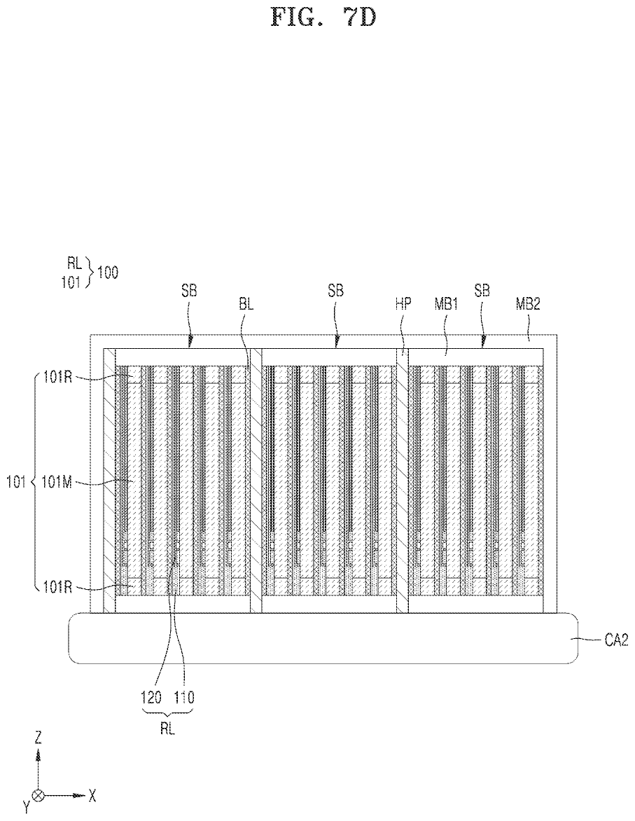

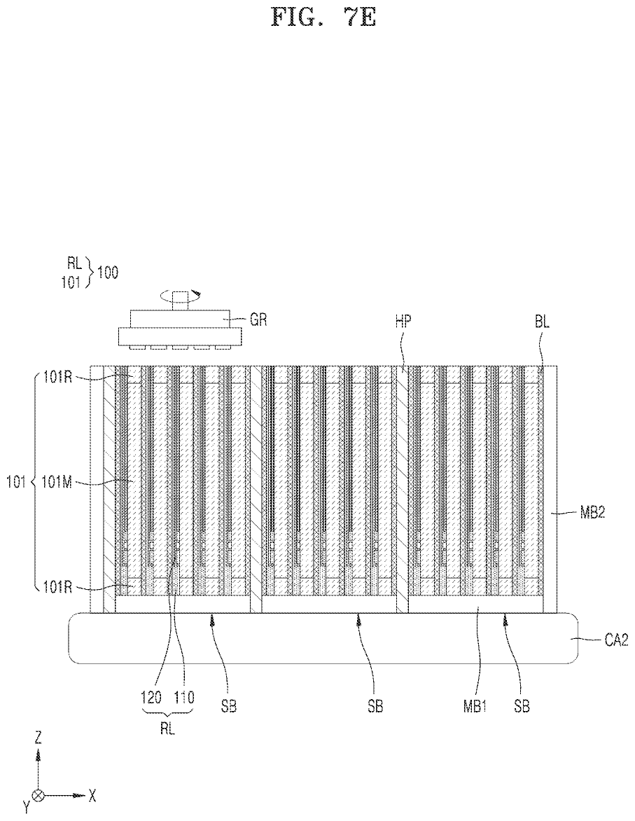

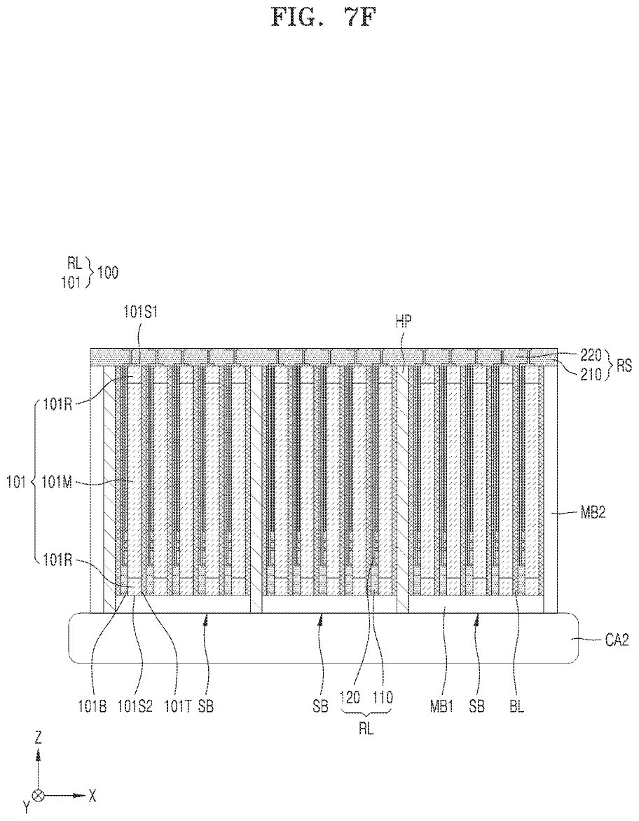

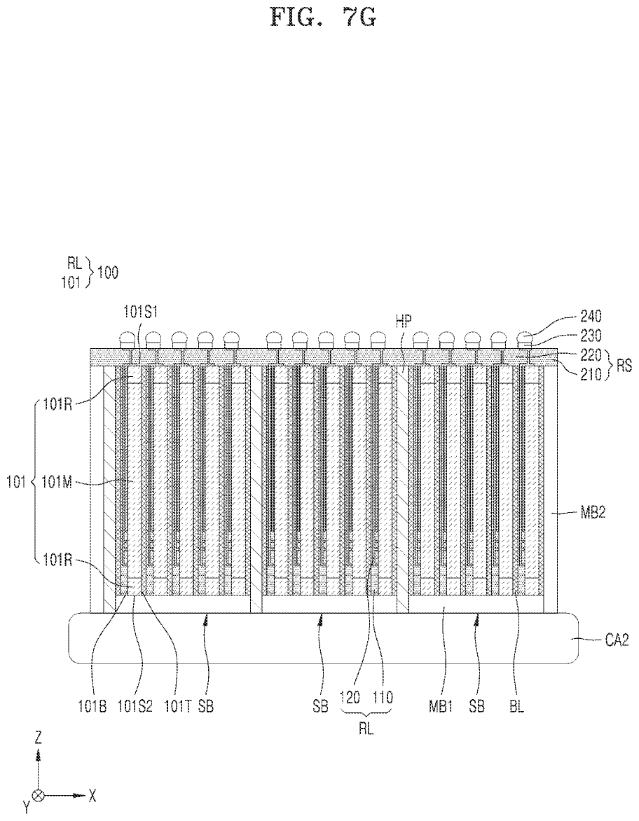

FIGS. 7A to 7G are related cross-sectional views further illustrating the method of manufacturing semiconductor packages according to embodiments of the inventive concept summarized in FIG. 6.

Referring to FIG. 7A, a semiconductor wafer WF may be provided that includes a plurality of previously fabricated and tested semiconductor chips 100, as well as relevant scribe lens SL among the plurality of semiconductor chips 100.

In this regard, the semiconductor wafer WF may be understood as a two-dimensional surface including an arrangement of semiconductor chips 100 previously fabricated using a sequence of manufacturing processes. Such fabrication of semiconductor chips 100 on the semiconductor wafer is well understood by those skilled in the art.

Here, each of the semiconductor chips 100 may include the semiconductor substrate 101 and the redistribution layer RL formed on a top surface of the semiconductor substrate 101.

The scribe lanes SL (e.g., straight rows of constant width and/or straight columns of constant width) may extend in the first and second horizontal directions on the semiconductor wafer WF to appropriately delineate spaces between adjacent ones of the semiconductor chips 100 and to delineate edges of the respective semiconductor chips 100.

Using the scribe lanes as a guide, the respective semiconductor chips 100 may singulated from the wafer WF using (e.g.,) a sawing process, a plasma etch process, etc. Once singulation of the semiconductor chips 100 is complete, each the resulting semiconductor chips 100 may include the semiconductor substrate 101 having the main area 101M and scribe lane areas 101R surrounding the main area 101M.

Referring to FIG. 7B, a number (e.g., 5) of singulated semiconductor chips 100 may be sequentially and vertically stacked (e.g., stacked in the vertical direction) on a first carrier substrate CS1 to form semiconductor blocks SB. Here, a heat dissipation plate HP may be disposed across top surfaces of uppermost semiconductor chips in the resulting semiconductor blocks SB. Of note, in some embodiments, the semiconductor chips 100 may be vertically stacked on the first carrier substrate CS1 for ease of manipulation and assembly.

The first carrier substrate CS1 may include, for example, glass, silicon (Si), or aluminum (Al) oxide. In order to better secure lowermost semiconductor chips in the resulting semiconductor blocks SB to the first carrier substrate CS1, an adhesive layer BL may be used.

In some embodiment, each of the semiconductor chips 100 may have the same purpose, structure, shape, and/or technical feature(s). For example, the semiconductor chips 100 may the same kind of memory chip. The semiconductor chips 100 may be attached to one another using (e.g.,) a die attach film, an adhesive layer BL, etc.

The first molding member MB1 may be provided to substantially surround the exterior of the semiconductor blocks SB, but leaving exposed top surfaces of uppermost semiconductor chips in the stacked semiconductor blocks SB.

Then, the heat dissipation plate HP may disposed on the first molding member MB1 and top surfaces of the uppermost semiconductor chips in the semiconductor blocks SB. In some embodiments, the heat dissipation plate HP may be provided as a single element substantially covering the top surfaces of the uppermost semiconductor chips in the semiconductor blocks SB and top surfaces of the first molding member MB1.

Thereafter, respective semiconductor blocks SB may be separated by cutting the heat dissipation plate HP and/or the first molding member MB1 along dicing lines DL.

Referring to FIG. 7C, once the semiconductor blocks SB have been successfully singulated, each of the semiconductor blocks SB may be rotated and “stood on edge.” With this orientation, the rotated semiconductor blocks SB may be arranged side by side on a second carrier substrate CS2 (e.g.,) in the first horizontal direction.

Thereafter, the semiconductor blocks SB may be separated from the first carrier substrate CS1 and attached onto the second carrier substrate CS2. Here, the second carrier substrate CS2 may include, for example, glass, Si, Al oxide, etc.

Accordingly, an exemplary semiconductor package manufacturing method, may include the combination: (1) vertically stacking N semiconductor chips, (2) adding the first molding member MB1 and/or the heat dissipation plate HP, (3) dicing the resulting structure into multiple semiconductor blocks SB, (4) rotating (or standing on edge) each of the separated semiconductor blocks SB in turn, and (5) laterally arranging the rotated semiconductor blocks SB on top of the second carrier substrate CS2. The resulting combination may yield laterally stacked semiconductor blocks SB, wherein each semiconductor block SB includes ‘N’, laterally stacked semiconductor chips 100. Further, with this configuration, the regularly spaced heat dissipation plates HP may effective exhaust heat from the laterally stacked semiconductor blocks SB.

Referring to FIG. 7D, the second molding member MB2 may then be formed on the second carrier substrate CS2 to substantially surround the laterally stacked semiconductor blocks SB.

Here, much like the first molding member MB1, the second molding member MB2 may protect the semiconductor blocks SB from external shock and/or contamination. The second molding member MB2 may include an epoxy mold compound or resin. In addition, the second molding member MB2 may be formed by a process such as compression molding, lamination, or screen printing.

Referring to FIG. 7E, a chemical and/or mechanical polishing process and/or a planarizing process may be applied to upwardly disposed edges of the semiconductor substrates 101, the redistribution layers RL, the adhesive layers BL and the heat dissipation plates HP, as well as portions of the first molding member MB1 and the second molding member MB2. For example, the polishing and planarizing process may be performed by applying a grinder GR to the collective, upwardly disposed edges. In this manner, the grinder GR action (optionally together with applied cleaning chemicals) may selectively remove upper portions of the semiconductor substrates 101, the redistribution layers RL, the adhesive layers BL and the heat dissipation plates HP, as well as portions of the first molding member MB1 and the second molding member MB2 in order to prepare a flat upper surface and to expose edge portions of at least the semiconductor substrates 101 and the redistribution layers RL.

Referring to FIG. 7F, once the flat upper surface has been prepared, the redistribution structure RS may be formed on the flat upper surface across the combination of the laterally stacked semiconductor blocks SB.

Here, the redistribution structure RS may variously connect the redistribution layers RL. For example, given the orientation of FIG. 7F, a bottom surface of the redistribution structure RS may directly contact (wholly or in part, the respective, upwardly-extending edges of the redistribution layers RL correspondingly associated with the semiconductor substrates 101. In addition, a top surface of the redistribution structure RS opposing the bottom surface of the redistribution structure RS may form another flat upper surface.

The redistribution structure RS may include the second insulating layer 210 and the second wiring layer 220. The second insulating layer 210 may include polymer, benzocyclobutene, or resin and, as occasion demands, photosensitive polyimide. In some embodiments, the second insulating layer 210 may include silicon oxide, silicon nitride, or silicon oxynitride. The second wiring layer 220 may include, for example, Cu, Ni, Au, Cr, Ti, Pd, or an alloy of the above metals. In some embodiments, the second wiring layer 220 may be formed by an electroplating process.

Referring to FIG. 7G, pillar layers 230 and connection terminals 240 may be sequentially formed on the flat upper surface of the redistribution structure RS.

In some embodiments, the connection terminals 240 may include solder balls (e.g., spherical solder balls) respectively attached to the pillar layers 230. In other embodiments, the connection terminals 240 may include one or more solder layers in the pillar layers 230, and the solder layers may be remelted by an applied reflow process in order to reflow the solder layers.

The, by removing the second carrier substrate CS2 from the resulting structure of FIG. 7G, the semiconductor package 10 of FIG. 1B may be completed.

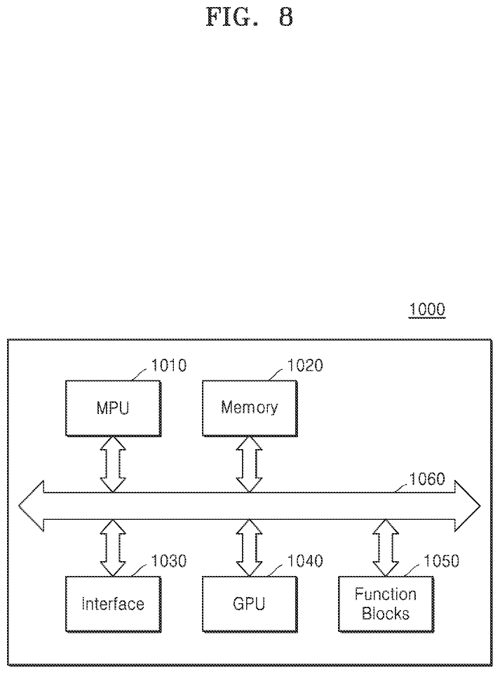

FIG. 8 is a block diagram illustrating one possible configuration for a semiconductor package 1000 according to embodiments of the inventive concept.

Referring to FIG. 8, the semiconductor package 1000 may include a micro-processing unit (MPU) 1010, memory 1020, an interface 1030, a graphics processing unit (GPU) 1040, function blocks 1050, and a bus 1060 connecting the above components to one another.

The semiconductor package 1000 may include both the MPU 1010 and the GPU 1040 or one of the MPU 1010 and the GPU 1040.

The MPU 1010 may include a core and a cache. For example, the MPU 1010 may include a multi-core. Cores in the multi-core may have the same performance or different performances. In addition, cores in the multi-core may be simultaneously activated or may be activated at different points in time.

The memory 1020 may store a result processed by the function blocks 1050 by control of the MPU 1010. The interface 1030 may transmit and receive information or signals to and from external devices. The GPU 1040 may perform graphic functions. For example, the GPU 1040 may perform the video codec or three-dimensional (3D) graphics. The function blocks 1050 may perform various functions. For example, when the semiconductor package 1000 is an application processor, such as that commonly used in mobile devices, some of the function blocks 1050 may further perform one or more communication function(s).

The semiconductor package 1000 may include one or more of the semiconductor packages 10, 20, 30, 40, and 50 described above.

While the inventive concept has been particularly shown and described with reference to embodiments thereof, it will be understood that various changes in form and details may be made therein without departing from the spirit and scope of the following claims.

What is claimed is:

1. A semiconductor package comprising:
laterally stacked semiconductor blocks disposed side by side in a first horizontal direction on a redistribution structure,
wherein each semiconductor block among the laterally stacked semiconductor blocks includes laterally stacked semiconductor chips, a heat dissipation plate, and a first molding member on the laterally stacked semiconductor chips.

2. The semiconductor package of claim 1, wherein each semiconductor block among the laterally stacked semiconductor blocks includes N laterally stacked semiconductor chips, where ‘N’ is a natural number greater than 1.

3. The semiconductor package of claim 1, wherein in each semiconductor block among the laterally stacked semiconductor blocks, the heat dissipation plate is laterally disposed to one side of the laterally stacked semiconductor chips.

4. The semiconductor package of claim 3, wherein the heat dissipation plate has a same thickness that ranges from between about 10 μm to about 30 μm.

5. The semiconductor package of claim 1, wherein each semiconductor chip in the laterally stacked semiconductor chips includes:
a semiconductor substrate including a main area configured to mount a semiconductor device and scribe lane areas surrounding the main area; and
a redistribution layer on the main area and the scribe lane areas, wherein the redistribution layer is electrically connected to the redistribution structure.

6. The semiconductor package of claim 5, wherein a top surface of the redistribution structure contacts respective downward extending edges of semiconductor substrates, respective downward extending edges of redistribution layers, respective downward extending edges of the heat dissipation plates, and a bottom surface of the molding member on a common horizontal plane.

7. The semiconductor package of claim 1, wherein adjacent semiconductor chips among the laterally stacked semiconductor chips are attached by an adhesive layer.

8. The semiconductor package of claim 1, wherein each semiconductor chip among the laterally stacked semiconductor chips has a first length in a vertical direction less than a second length of the heat dissipation plate.

9. The semiconductor package of claim 8, wherein each semiconductor chip among the laterally stacked semiconductor chips has a first planar area less than a second planar area of the heat dissipation plate.

10. The semiconductor package of claim 1, further comprising:
a second molding member on side surfaces of the laterally stacked semiconductor blocks.

11. A semiconductor package comprising:
a redistribution structure extending in a first horizontal direction;
solder bumps arranged on a bottom surface of the redistribution structure; and
laterally stacked semiconductor blocks arranged side by side on a top surface of the redistribution structure,
wherein adjacent semiconductor blocks among the laterally stacked semiconductor blocks are separated by a heat dissipation plate,
each of the laterally stacked semiconductor blocks includes laterally stacked semiconductor chips and a first molding layer on the laterally stacked semiconductor chips, and
each semiconductor chip among the laterally stacked semiconductor chips includes a semiconductor substrate and a redistribution layer on the semiconductor substrate.

12. The semiconductor package of claim 11, wherein each of the laterally stacked semiconductor blocks is cube-shaped and has the same size.

13. The semiconductor package of claim 11, wherein respective downward extending edges of semiconductor substrates associated with the laterally stacked semiconductor chips, respective downward extending edges of redistribution layers associated with the laterally stacked semiconductor chips, and downward extending edge of heat dissipation plates associated with the laterally stacked semiconductor blocks contact the top surface of the redistribution structure.

14. The semiconductor package of claim 13, wherein the respective redistribution layers associated with the laterally stacked semiconductor chips are electrically connected to the redistribution structure.

15. The semiconductor package of claim 14, wherein each of the semiconductor chips among the laterally stacked semiconductor chips is a same type of memory chip.

16. A semiconductor package comprising:
a laterally stacked plurality of semiconductor chips, wherein each semiconductor chip among the laterally stacked plurality of semiconductor chips includes; a semiconductor substrate having an active surface and an opposing inactive surface facing, a first side and an opposing second side respectively connecting the active surface and the inactive surface, and a redistribution layer on the active surface;
adhesive layers respectively disposed between adjacent ones of the laterally stacked plurality of semiconductor chips;
a redistribution structure extending in a first horizontal direction, wherein the laterally stacked plurality of semiconductor chips is disposed on a top surface of the redistribution structure, such each first side of the laterally stacked plurality of semiconductor chips contacts the top surface of the redistribution structure;
a plurality of heat dissipation plates, wherein each heat dissipation plate among the plurality of heat dissipation plates is respectively disposed at a regular interval among the laterally stacked plurality of semiconductor chips; and
a first molding member covering at least two second sides of the laterally stacked plurality of semiconductor chips and exposing an end portion of each one of the plurality of heat dissipation plates.

17. The semiconductor package of claim 16, further comprising:
a semiconductor device disposed on each active surface of each semiconductor substrate for each one of the laterally stacked plurality of semiconductor chips,
wherein the semiconductor device is electrically connected to a corresponding redistribution layer, and the corresponding redistribution layer is electrically connected to the redistribution structure.

18. The semiconductor package of claim 17, wherein the semiconductor device includes at least one memory device.

19. The semiconductor package of claim 16, further comprising:
a second molding member disposed on the top surface of the redistribution structure and surrounding outer lateral surfaces of the laterally stacked plurality of semiconductor chips.

20. The semiconductor package of claim 16, wherein a same number of semiconductor chips among the laterally stacked plurality of semiconductor chips are disposed between neighboring heat dissipation plates among the plurality of heat dissipation plates.
